(19) United States
(12) Patent Application Publication
(10) Pub. No.: US 2011/0195579 A1
(43) Pub. Date: Aug. 11, 2011

(54) SCRIBE-LINE DRAINING DURING WET-BENCH ETCH AND CLEAN PROCESSES

(75) Inventor: Yi-Tung YEN, Hsinchu City (TW)

(73) Assignee: TAIWAN SEMICONDUCTOR MANUFACTURING COMPANY, LTD., Hsinchu (TW)

(21) Appl. No.: 12/704,010

(22) Filed: Feb. 11, 2010

(51) Int. Cl. H01L 21/306; B08B 3/00

(52) U.S. Cl. 438/747; 134/26; 257/E21.219

(57) ABSTRACT

Controlling scribe line orientation during wet-bench processes has been found to improve yield and reduce particles from inadequate draining when the scribe lines are oriented about 45 degrees from horizontal. A wafer is provided to the wet bench apparatus and immersed in a solution. When removed from the solution, the wafer should be oriented vertically with scribe lines oriented about 45 degrees, plus or minus 15 degrees from horizontal. Wafer scribe line orientation are checked and changed before the wet bench process or during the wet bench processing.

### FIELD OF THE INVENTION

The present invention relates, most generally, to semiconductor device manufacturing. More particularly, the present invention relates to methods and systems for etching, stripping, cleaning and other wet processing operations.

### BACKGROUND

Semiconductor devices are formed on semiconductor substrates using a manufacturing process that typically includes several wet chemical-processing operations. The wet processing operations include cleaning operations, stripping operations and etching operations in which the chemicals in a chemical bath react with a material such as a film or other material that is to be cleaned, etched or removed. The use of wet chemical benches to perform these operations has been and continues to be a standard in the semiconductor manufacturing industry.

As devices become more complex, feature sizes become more miniaturized and film thicknesses become reduced, so the size and number of defects that can reduce yield also are also reduced. Thus, it becomes increasingly important to eliminate contamination at all stages of the manufacturing process. Sources of contamination during wet chemical processing include watermarks, particles from the wafer, and settling precipitates. A watermark forms when a water drop adheres to the wafer surface during the period in which the state of the wafer is changed from a wet state to a dry state. Although the adherent water drop evaporates by drying, a mark of the water drop remains after the water drop disappears. One way to reduce watermarks is to remove the water drop before the wafer dries. Another source of contamination is particles from the wafer itself. Material removed from structures on the wafer during a previous process, such as dry etching or ashing, and materials etched during the wet process itself, sometimes stay on the wafer after the wet process. If incorporated into the structure in a subsequent operation, these materials can cause shorts or functional irregularity enough to cause a die to be rejected. Yet another source of contamination is the solution in which the wafer is immersed. Material removed from previous batches and precipitates from the reactive chemicals in the solution can settle or deposit onto the wafer. If not removed, these particles can also be incorporated into a subsequent film and cause problems.

It is therefore desirable to remove as many contaminants as possible, including the wet chemicals and particles, from the wafer surface after a wet process.

### SUMMARY OF THE INVENTION

To address these and other needs, one aspect of the invention provides a method for reducing contaminants from wet processes by improving draining when the wafer is removed from a wet chemical process. Improved draining reduces the amount of liquid residue remaining on the wafer that can cause watermarks. Improved draining also reduces particles left over on the wafer, either from the wafer itself or from particulates in the wet chemical. The yield of the semiconductor product attributable to the wet processing is improved.

In accordance with various embodiments, a method of processing a wafer includes providing a wafer having a plurality of perpendicular scribe lines thereon. Scribe lines demarcate the boundary between different dies and are used ultimately to separate the various dies on the same wafer into different semiconductor products by cutting or sawing according to the scribe lines. Most dies are rectangular thus having perpendicular scribe lines.

In one aspect of methods in accordance with the invention the wafer is immersed in a first solution. The wafer is typically held in a wafer holder or cassette and lowered into a solution bath containing the wet chemical. However, it is envisioned in some wet processing the wafer may be held by a robot arm and immersed individually outside of a cassette or holder. The first solution may be a reactive wet chemical for etching, a rinse agent, or a cleanser. To achieve a desired amount of material removal or cleaning, the immersion would occur for a requisite amount of time depending on process requirements. The wafer is then removed from the first solution, usually by raising the wafer holder from the solution. The wafer is positioned such that while the wafer is held vertically and the plurality of perpendicular scribe lines form angles of 30-60 degrees from horizontal. Thus held, the first solution drains away from the wafer in an improved fashion leaving less contamination behind.

In certain embodiments, the wafer position during the removing operation is vertical and the scribe lines form angles of about 45 degrees from horizontal. The wafer may be rotated into the correct orientation before it is immersed in the first solution. In certain cases, the entire wafer cassette or carrier holding multiple wafers may be rotated before during or after immersing the wafer in the first solution. The method may also include transferring the wafer to a second solution, immersing the wafer in a second solution, and removing the wafer from the second solution, again draining the wafer in the correct orientation of having perpendicular scribe lines form angles of 30-60 degrees from horizontal. The method may also include drying the wafer after sufficient draining has occurred. Note that drying the wafer too quickly may leave the watermark residue. The second solution may be deionized water, a reactive wet chemical for etching, a rinse agent, or a cleanser.

In another aspect, embodiments of the methods in accordance with the present invention pertain to providing a wafer having scribe lines thereon; orienting the wafer such that no scribe line is less than 30 degrees from horizontal; vertically immersing the oriented wafer in a first solution; removing the wafer from the first solution; and allowing the first solution to drain away from the wafer while maintaining a vertical wafer position and a scribe line orientation of no less than 30 degrees from horizontal. As described above, most scribe lines intersect at 90 degrees because most dies are rectangular. However, other die shapes are possible and the methods of the present invention are equally applicable to other die shapes as long as no scribe line is less than 30 degrees from horizontal. The first solution may be an etchant, i.e., phosphoric acid, sulfuric acid, or hydrofluoric acid, a rinse agent, or cleanser.

In yet another aspect, embodiments of the methods in accordance with the present invention pertain to providing a plurality of wafers having scribe lines thereon, said plurality of wafers being held in a container, immersing the container in a solution by lowering the container into a solution bath; removing the container from the solution bath; and, draining the solution away from the plurality of wafers and the container. The plurality of wafers are vertically oriented such that the scribe lines are about 45 degrees from horizontal, which may be about 35-55 degrees from horizontal. In some cases, the draining occurs with the wafers being held vertically with the scribe lines being about 45 degrees from horizontal. Using a wafer cassette that is lowered into and raised out of a solution bath, the amount of time taken to lower and to raise the cassette may be much shorter, for example, one order of magnitude shorter, than the duration the entire cassette is immersed.

These and other features and advantages of embodiments of the present invention are best understood from the following detailed description when read in conjunction with the accompanying drawings.

### BRIEF DESCRIPTION OF THE DRAWING

It is emphasized that, according to common practice, the various features of the drawing are not necessarily to scale. On the contrary, the dimensions of the various features are arbitrarily expanded or reduced for clarity.

FIG. 1 is a schematic view showing a processing bath and wafer cassettes used in certain embodiments of the present invention.

FIGS. 2A and 2B are schematic representations of contaminant flow during the draining process that occurs at different wafer orientations.

FIG. 3 is a schematic representation of the scribe line angles on a wafer held by a cassette.

FIG. 4 is a flowchart that illustrates a method in accordance with various embodiments of the present invention.

FIGS. 5A and 5B are wafer particle maps showing cleaning results for a method in accordance with an embodiment of the present invention and for a baseline method.

FIGS. 6A and 6B are wafer particle maps showing cleaning results for a method in accordance with an embodiment of the present invention and for a baseline method.

### DETAILED DESCRIPTION OF SPECIFIC EMBODIMENTS

Provided are methods and systems that may be used in conjunction with the type of chemical or wet baths used in the manufacture of semiconductor devices. The methods and systems are applicable to various chemistries and although the following description will often be with respect to a wet etch; such is intended to be exemplary only and not limiting of the applications of the invention. According to other embodiments, the methods of the present invention are also applicable to other wet chemical processes such as cleaning or rinsing processes.

On a wafer, scribe lines demarcate the boundary between different dies and are used ultimately to separate the various dies on the same wafer into different semiconductor products by cutting or sawing according to the scribe lines. Most dies are rectangular so that the scribe lines intersect each other at 90 degrees; however, scribe lines need not be perpendicular as long as the dies fill the surface of the wafer in a repeating pattern that does not leave too much unused area on the wafer. For example, a number of rhombus shaped dies or hexagon shaped dies may be used. With the use laser cutting of dies, scribe lines that are not straight may be accommodated, allowing the use of a variety of die shapes.

Wet chemical processes are often used to remove material from semiconductor structures by dissolving unwanted material or removing surface particulates. Fine-tuned control for wet chemical processes is typically harder to achieve than for dry processes, because the properties of the liquid chemical solutions typically change over time. Various semiconductor processes may occur before a wafer arrives at the wet bench. For example, a wafer may experience additional processes such as dry etching, ashing, deposition, or other wet processes before it is subjected to a particular wet chemical process. Many of these additional processes may leave unwanted particles on the surface of the wafer. For example, during etching some of the etched materials may redeposit on the wafer and these materials are preferably removed during the subsequent wet processing.

When a container of wafers arrives at a wet bench station, the individual wafers in the container may or may not be inspected or sorted in a sorter. A sorter may change the order of the wafers in a container or remove some wafers and insert others. A sorter can also rotate some or all of the wafers in a container based on operator input. Typically, the wafers in one container have been processed previously in the same tool and are oriented the same way. In a single wafer tool, wafers are usually re-oriented before processing starts. At the end of the processing in the tool, the orientation of the wafers may have shifted slightly, but not significantly. However, human issues or calibration of the robot as wafers are inserted into a container may cause the wafers in a container to have slightly different orientations. Typically, the wafers in a container processed in a single wafer tool arrive at a wet bench oriented so that one set of scribe lines is horizontal. In case of cumulative calibration errors, the scribe lines may be off of horizontal by 5, 10, or as much as 15 degrees.

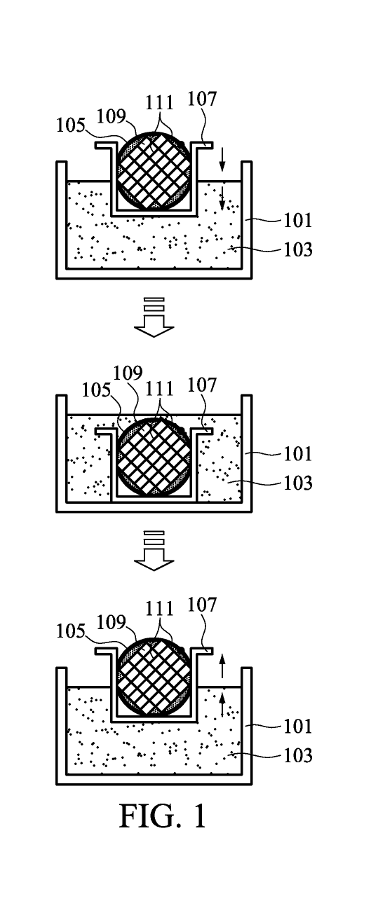

FIG. 1 shows a portion of a process at a wet bench. The container, cassette, or holder 107 of wafers 105 may be held by robot arms (not shown) above a solution bath enclosure 101. The container 107 is lowered into the solution 103 with the wafers 105 in a mostly vertical (i.e., on their edges) position. As shown, each of the wafers 105 include a number of dies 109 separated by scribe lines 111. Holes (not shown) on the sides or bottom of the container 107 allow the solution 103 to enter the container so that the wafers are completely immersed as shown in FIG. 1B. After a requisite amount of time dictated by process requirements, the container 107 is lifted from the bath as shown in FIG. 1C and any remaining solution is allowed to drain away from the wafers and container.

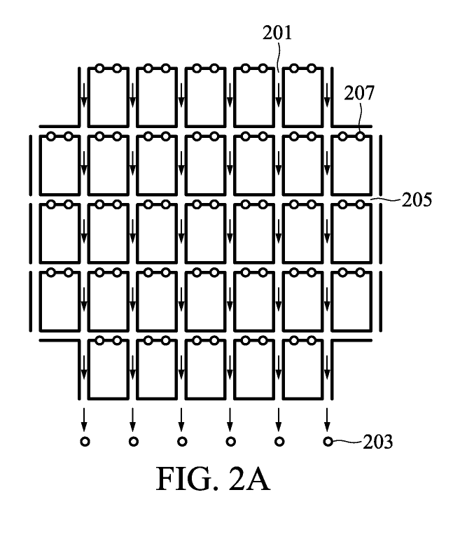

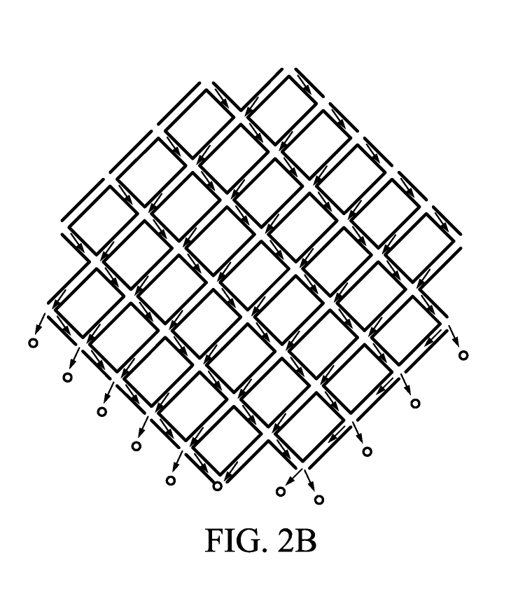

It is believed that horizontal or substantially horizontal scribe lines bar liquid flow and decrease the capability of liquid to drain completely off the wafer after the conclusion of a wet process. Particles do not drain away easily as shown in FIG. 2A. As the liquid drains away through the vertical scribe lines 201, few if any of the particles 203 are carried away. Particles 207 remaining on the horizontal scribe lines 205 may become stuck when the fluid drag over the faces of the dies becomes less than the adhesive force of the particle on the surface. Even when particles are carried away by the fluid draining down the face of dies, it may still become stuck on the die or at the next horizontal scribe line. As discussed above, particles on the surface of the die may be incorporated in the next deposited film and cause the die to fail. The horizontal scribe lines also retain water drops that can form water marks when the wafer is dried.

To improve drainage of particles and liquid, the wafer is drained at an angle as shown in FIG. 2B. The orientation of the wafer that results in improved drainage is the optimum draining position. It is believed that draining at an angle reduces the likelihood that a particle would become stuck because drainage is aided by gravity as well as fluid drag. Further, water marking is reduced because water drops are less likely to be stuck with gravity's constant pull at an angle. It is also believed that drainage down various angled scribe lines are able to combine to produce a larger overall drag force that tends to move particles better than when one set of scribe lines is horizontal.

The use of angled scribe lines also improves process control and uniformity. With smaller features and decreasing thicknesses to be etched, the timing control to etch the correct amount of material becomes more important. As noted above, having scribe lines in the horizontal position can retain fluid drops. If the fluid is a reactive wet chemical, then the additional time between draining and transferring to the next solution bath, which may in terms of second or minutes, can cause unwanted etching to occur and reduce process control. As drainage improves, more of the fluid drains away so less is left to continue etching the material. This improved process control is especially important for the smaller geometries at 0.13 μm and below.

The optimum draining position also includes having the wafer being substantially vertical relative to the solution bath. Tilting the wafer tends to reduce the gravitational forces that aid drainage. However, some tilting may be envisioned to improve initial fluid flow. When held in a cassette slot, the wafers may tilt in a very small angle within the slot. Such tilting still maintains the wafers in a substantially vertical position.

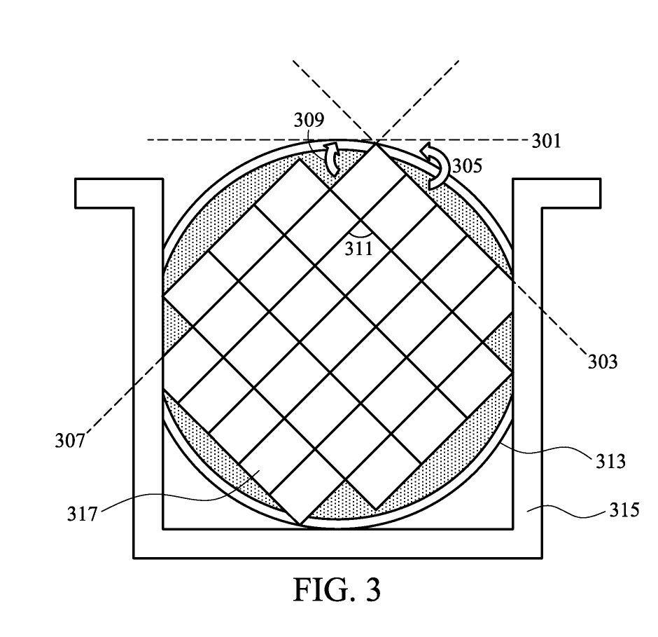

FIG. 3 shows scribe line angles on a wafer. A container 315 holds a wafer 313 having a number of dies 317. The dies 317 are rectangular and are bound by sets of scribe lines. The angle 305 represents the angle that scribe line 303 forms with respect to the horizontal 301. The angle 309 represents the angle that scribe line 307 forms with respect to the horizontal 301. The angle 311 represents an angle formed by the intersection between sets of scribe lines (e.g., the angle between scribe line 303 and scribe line 307). Scribe line angles 305 and 309 need not be the same. However, having angles 305 and 309 be about 45 degrees provides better drainage and particle performance. In various embodiments angles 305 and 309 are greater than about 30 degrees, or between about 30-60 degrees for perpendicular scribe lines, or between about 35-55 degrees. These embodiments provide significant contamination and yield improvements over the situation in which one set of scribe lines is substantially horizontal. If non-rectangular dies are used, as long as the angles 305 and 309 formed by the scribe lines relative to the horizontal are greater than about 30 degrees, then the improvement in drainage is realized.

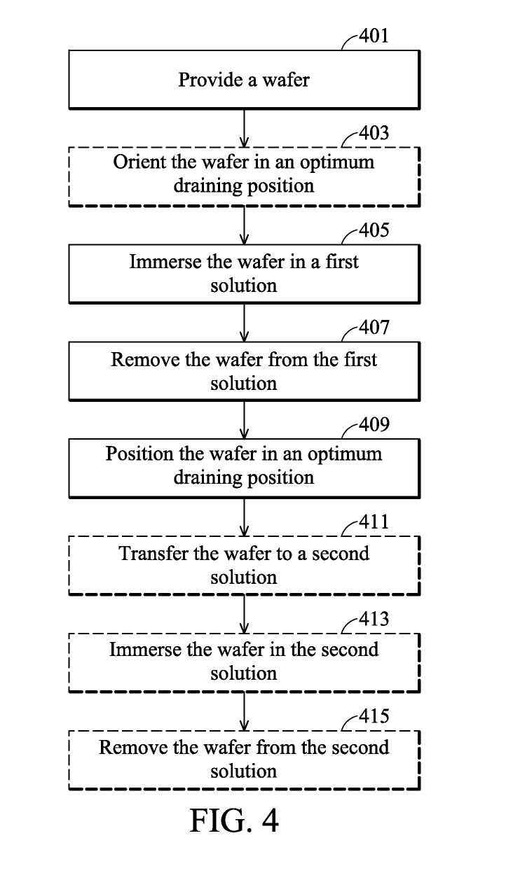

FIG. 4 is a flow chart illustrating an exemplary method according to various embodiments of the invention. A wafer is provided in operation 401. Typically, the wafer has a number of scribe lines thereon demarcating boundaries of dies on the wafer. The scribe lines may or may not intersect at right angles. The wafer may be held in a container, cassette, or a wafer holder/carrier. In certain wet clean apparatuses, the wafer may be held singly. At this point, before the wafer is introduced to the first solution, the wafer may be rotated or oriented to an optimum draining position in operation 403. This optimum draining position is defined by having the scribe lines form angles between 30 and 60 degrees from horizontal and holding the wafer vertically, i.e., on its edge, relative to the solution bath. Although the wafer may be oriented to this position at this time, the position must be maintained when the solution is drained.

The wafer is immersed in a first solution in operation 405. The wafer is typically lowered into the first solution. If the wafer is in a container, then a robot arm may be used to lower the entire container into a solution bath. In some embodiments, a robot arm may hold the wafer and lower it into the solution. After immersing the wafer for an amount of time required for the process, the wafer is then removed from the first solution in operation 407. Typically, this entails raising a container of wafers from the solution, after which the solution would start to drain away from the container and the wafers.

In operation 409, the wafer is positioned in an optimum draining position, the position as described above in operation 403. This operation should occur as the solution drains from the wafer or before. After the wafer drains, it may be transferred to a second solution in operation 411. A second solution that is different from the first solution may be used to further clean or etch the wafer. The wafer is immersed in the second solution in operation 413 and then removed from the second solution in operation 415.

Various experiments were conducted to compare the effects of the methods of the present invention. In one case of silicon nitride etching, the yield of wafers having rotated scribe lines at 45 degrees (59% yield) improved significantly over those that have not been rotated (42% yield) and those that have been rotated at 90 degrees (38% yield). It is believed that a rotation of 90 degrees actually decreases and did not improve yield because one set of scribe lines is still substantially horizontal. A comparison of the actual defects shows that the improvements resulted mostly from changes in particle counts.

In other experiments, 0.13 μm technology wafers with high voltage devices were tested. In two different wet processes (a polysilicon loop process and a lightly doped drain (LDD) loop process) the particle counts of a rotated wafer were half of that of a non-rotated wafer.

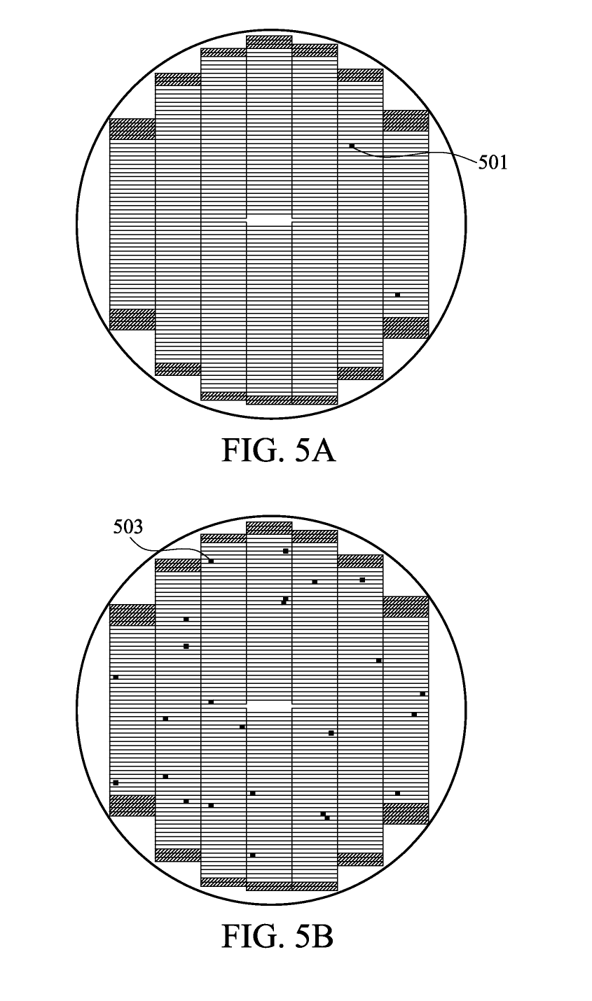

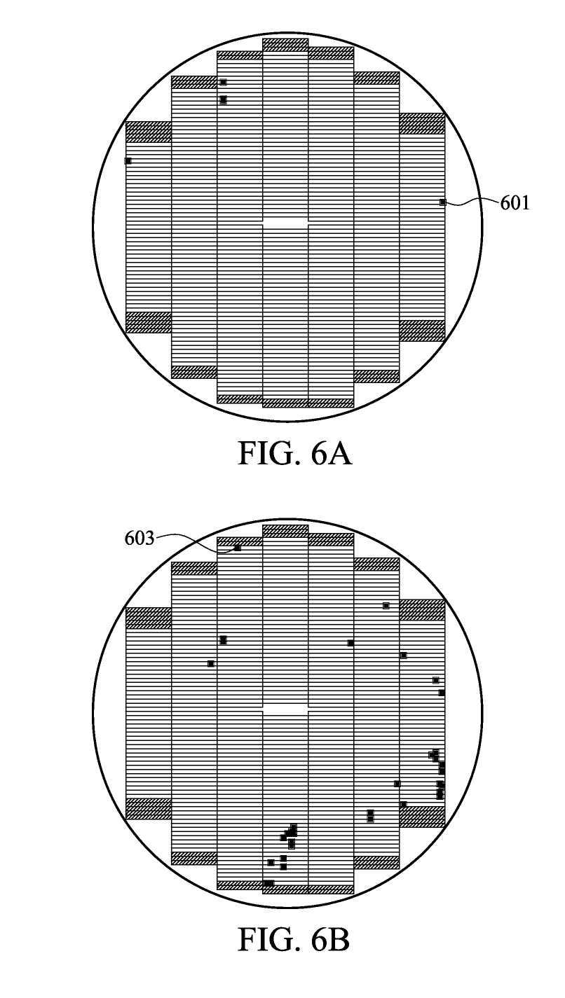

In yet other experiments, dramatic differences were noted between wafers that were rotated to a 45-degree scribe line angle and those that were not. In one case particle-based defects were not detected at all for the rotated batch and detected an average of 0.68 per wafer for the non-rotated batch. In cases where a follow on wet clean step was performed after a wet stripping process, the rotated wafers averaged fewer particles by one order of magnitude. After a photoresist strip, the wafer with 45-degree scribe line angle had particles in 7 dies and the non-rotated wafer had particles in 49 dies. FIGS. 5A and 5B show the wafer particle mapping for the rotated wafer and non-rotated wafer. After the subsequent wet clean, the rotated wafer had particles (501) in only 2 dies and the non-rotated wafer had 25 dies with particles (503), which is more than the rotated batch even without the subsequent wet clean. According to this data, it is possible to remove an entire wet clean process and yet still improve particle performance. In another case after a resist protective oxide clean, the wafer with 45-degree scribe line angle had particles in 4 dies and the non-rotated wafer had particles in 53 dies for an order of magnitude improvement as shown in the wafer particle maps of FIGS. 6A and 6B.

The preceding merely illustrates the principles of the invention. It will thus be appreciated that those skilled in the art will be able to devise various arrangements that, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method for processing a wafer, said method comprising:
providing a wafer having a plurality of perpendicular scribe lines thereon;
immersing the wafer in a first solution;
removing the wafer from the first solution; and,
positioning the wafer such that the first solution drains away from the wafer while the wafer is held vertically and the plurality of perpendicular scribe lines form angles of 30-60 degrees from horizontal.

2. The method of claim 1, wherein the wafer position during the removing operation is vertical and that the plurality of perpendicular scribe lines form angles of about 45 degrees from horizontal.

3. The method of claim 1, further comprising rotating the wafer before immersing the wafer.

4. The method of claim 1, further comprising rotating a wafer carrier containing a plurality of wafers before immersing the wafer.

5. The method of claim 1, further comprising:
transferring the wafer to a second solution;
immersing the wafer in a second solution; and,
removing the wafer from the second solution while the wafer is held vertically and the plurality of perpendicular scribe lines form angles of 30-60 degrees from horizontal.

6. The method of claim 5, wherein the second solution is deionized water.

7. The method of claim 1, further comprising drying the wafer.

8. The method of claim 1, wherein the first solution is an etchant, a rinse agent, or cleanser.

9. A method for processing a wafer, said method comprising:
providing a wafer having scribe lines thereon;
orienting the wafer such that no scribe line is less than 30 degrees from horizontal;
vertically immersing the oriented wafer in a first solution;
removing the wafer from the first solution; and,
allowing the first solution to drain away from the wafer while maintaining a vertical wafer position and a scribe line orientation of no less than 30 degrees from horizontal.

10. The method of claim 9, wherein the wafer position during the removing operation is vertical and that the plurality of perpendicular scribe lines form angles of 30-60 degrees from horizontal.

11. The method of claim 9, further comprising rotating the wafer before immersing the wafer.

12. The method of claim 9, further comprising rotating a wafer carrier containing a plurality of wafers before immersing the wafer.

13. The method of claim 9, further comprising:
transferring the wafer to a second solution;
immersing the wafer in a second solution; and,
removing the wafer from the second solution while the wafer is held vertically and the plurality of perpendicular scribe lines form angles of 30-60 degrees from horizontal.

14. The method of claim 13, wherein the second solution is deionized water.

15. The method of claim 9, further comprising drying the wafer.

16. The method of claim 9, wherein the first solution is an etchant, a rinse agent, or cleanser.

17. The method of claim 9, wherein the first solution comprises phosphoric acid, sulfuric acid, or hydrofluoric acid.

18. A method for processing a wafer, said method comprising:
providing a plurality of wafers having scribe lines thereon, said plurality of wafers being held in a container and vertically oriented such that the scribe lines are about 45 degrees from horizontal;
immersing the container in a solution by lowering the container into a solution bath;
removing the container from the solution bath; and,
draining the solution away from the plurality of wafers and the container.

19. The method of claim 18, wherein about 45 degrees from horizontal includes a range of 35 to 55 degrees from horizontal.

20. The method of claim 18, wherein the wafer orientation is maintained vertically with the scribe lines being about 45 degrees from horizontal during the draining operation.

21. The method of claim 18, wherein a time duration to move the container into and out of the solution is about one order of magnitude shorter than a duration the entire container is immersed in the solution.
